(19) United States
(12) Patent Application Publication
(10) Pub. No.: US 2014/0137893 A1
(43) Pub. Date: May 22, 2014

(54) SUBSTRATE PROCESSING APPARATUS, SUBSTRATE PROCESSING METHOD AND STORAGE MEDIUM

(71) Applicant: Tokyo Electron Limited, Tokyo (JP)

(72) Inventors: Takahisa Otsuka, Koshi City (JP); Nobuhiro Ogata, Koshi City (JP); Hiroshi Marumoto, Koshi City (JP); Terufumi Wakiyama, Koshi City (JP)

(73) Assignee: Tokyo Electron Limited, Tokyo (JP)

(21) Appl. No.: 14/083,673

(22) Filed: Nov. 19, 2013

(30) Foreign Application Priority Data
Nov. 20, 2012 (JP) 2012-254424

(51) Int. Cl. H01L 21/67; H01L 21/02

(52) U.S. Cl. CPC H01L 21/6704; H01L 21/02041
USPC 134/18; 134/95.2; 134/30

(57) ABSTRACT

In example embodiments, a supply flow rate of a clean gas can be reduced without decreasing process performance. A flow rate of a clean gas 78, having a low humidity, supplied from a clean gas supply device 70 or 78 when a drying process is performed on a substrate is set to be smaller than a flow rate of a clean gas 70 supplied from the clean gas supply device 70 or 78 into an internal space within a housing 60 when a liquid process is performed onto the substrate W, and a flow rate of a gas exhausted through the housing exhaust path when the drying process is performed is set to be smaller than a flow rate of a gas exhausted through the housing exhaust path 64 when the liquid process is performed.

### CROSS-REFERENCE TO RELATED APPLICATION

This application claims the benefit of Japanese Patent Application No. 2012-254424 filed on Nov. 20, 2012, the entire disclosures of which are incorporated herein by reference

### TECHNICAL FIELD

The embodiments described herein pertain generally to a technique for controlling a supply of a clean gas and an exhaust of an atmosphere in an internal space of a housing of a substrate processing apparatus equipped with a cup configured to collect a processing liquid dispersed from a substrate being rotated in the internal space of the housing.

### BACKGROUND

A liquid process (for example, a cleaning process), one of processes in the course of manufacturing a semiconductor device, is performed by supplying a processing liquid (for example, a chemical liquid) onto a substrate such as a semiconductor wafer (hereinafter, simply referred to as “wafer”). After the liquid process of supplying the processing liquid, a rinse process of supplying a rinse liquid to remove the processing liquid and a drying process of drying the wafer are performed in sequence.

An example substrate processing apparatus configured to perform these processes is described in Patent Document 1. This substrate processing apparatus includes a spin chuck configured to hold a wafer thereon horizontally and rotate the wafer about a vertical axis line; and a cup that is disposed to surround the wafer and configured to collect a processing liquid dispersed from the wafer. The spin chuck and the cup are accommodated in a housing called a processing chamber. In order to maintain a clean atmosphere within the housing, a clean gas discharging device is provided at a ceiling of the housing, and a downflow of a clean gas flowing from the ceiling toward a bottom of the housing is formed in an internal space of the housing. Typically, the clean gas may be supplied by a FFU (Fan Filter Unit). The FFU is configured to filter air, which is introduced into a clean room by a fan, by an ULPA filter and supply the clean air. The FFU can supply the clean gas at a relatively low cost.

In order to suppress formation of a watermark on a surface of the wafer after a drying process, it may be desirable to reduce the humidity of an atmosphere around the wafer while performing the drying process. Since the humidity of the clean air supplied by the FFU is not sufficiently low, dry air or a nitrogen gas may be supplied into a space around the wafer during the drying process. As compared to the clean air supplied by the FFU, however, the nitrogen gas is of a high price. Further, since the dry air is supplied by using a dehumidification device, which is operated when the substrate processing apparatus is operated, a high cost is also required to use the dry air, as compared to the clean air supplied by the FFU. Further, recently, a substrate processing system equipped with a multiple number of substrate processing apparatuses is generally employed. It may not be desirable to supply a large amount of dry air into the multiple number of substrate processing apparatuses at the same time because it may increase a load on the humidification device. For these reasons, it is desirable to reduce the amount of the dry air or the nitrogen gas.

In Patent Document 1, dry air is supplied into the internal space of the housing only when drying the wafer after completing a liquid process using a chemical liquid configured to increase the hydrophobic property of the wafer. Except for this case, clean air is supplied by the FFU. In this way, the use of the dry air that may cause a load on the dehumidification device can be reduced.
Patent Document 1: Japanese Patent Laid-open Publication No. 2008-219047

### SUMMARY

In view of the foregoing, example embodiments provide a technique capable of reducing a supply flow rate of dry air or a nitrogen gas without decreasing process performance.

In one example embodiment, a substrate processing apparatus includes a substrate holding unit configured to hold thereon a substrate horizontally; a rotation driving unit configured to rotate the substrate holding unit about a vertical axis line; a processing liquid nozzle configured to supply a processing liquid onto the substrate; a cup unit, having a top opening and surrounding the substrate held on the substrate holding unit, configured to collect the processing liquid; a housing having an internal space in which the substrate holding unit, the processing liquid nozzle and the cup unit are accommodated; a clean gas supply device configured to selectively supply a first clean gas and a second clean gas having a humidity lower than that of the first clean gas into a space above the cup unit within the internal space of the housing; a cup exhaust path through which an atmosphere within the cup unit is exhausted; a housing exhaust path, having an exhaust opening formed at a position in the internal space of the housing and at an outside of the cup unit, through which an atmosphere in the internal space of the housing is exhausted without passing through an inside of the cup unit; an exhaust flow rate controller provided on the housing exhaust path; and a controller configured to control the exhaust flow rate controller such that a flow rate of the second clean gas supplied when a drying process is performed on the substrate is set to be smaller than a flow rate of the first clean gas supplied when a liquid process is performed by supplying the processing liquid onto the substrate from the processing liquid nozzle, and such that a flow rate of a gas exhausted through the housing exhaust path when the drying process is performed is set to be smaller than a flow rate of a gas exhausted through the housing exhaust path when the liquid process is performed.

In another example embodiment, a substrate processing method is performed by using a substrate processing apparatus including a substrate holding unit configured to hold thereon a substrate horizontally; a rotation driving unit configured to rotate the substrate holding unit about a vertical axis line; a processing liquid nozzle configured to supply a processing liquid onto the substrate; a cup unit having a top opening and surrounding the substrate held on the substrate holding unit, configured to collect the processing liquid; a housing having an internal space in which the substrate holding unit, the processing liquid nozzle and the cup unit are accommodated; a clean gas supply device configured to selectively supply a first clean gas and a second clean gas having a humidity lower than that of the first clean gas into a space above the cup unit in the internal space of the housing; a cup exhaust path through which an atmosphere within the cup unit is exhausted; a housing exhaust path, having an exhaust opening formed at a position in the internal space of the housing and at an outside of the cup unit, through which an atmosphere in the internal space of the housing is exhausted without passing through an inside of the cup unit; and an exhaust flow rate controller provided on the housing exhaust path. The substrate processing method includes setting a flow rate of the second clean gas supplied when a drying process is performed on the substrate to be smaller than a flow rate of the first clean gas supplied when a liquid process is performed by supplying the processing liquid onto the substrate from the processing liquid nozzle; and setting a flow rate of a gas exhausted through the housing exhaust path when the drying process is performed to be smaller than a flow rate of a gas exhausted through the housing exhaust path when the liquid process is performed.

In still another example embodiment, a computer-readable storage medium may store thereon computer-executable instructions that, in response to execution, cause a substrate processing apparatus to perform a substrate processing method. Here, the computer-executable instructions stored on the storage medium may be executed by the controller, which is formed of a computer, of the substrate processing apparatus, and the controller may control the substrate processing apparatus.

The first clean gas may be air within a clean room supplied and filtered by a fan filter unit, and the second clean gas may be clean dry air or a nitrogen gas.

The substrate processing apparatus may further include a drying accelerating fluid nozzle configured to supply a drying accelerating fluid onto the substrate when the drying process is performed, and the drying accelerating fluid may include isopropyl alcohol.

In accordance with the example embodiments, the exhaust flow rate through the housing exhaust path can be reduced without decreasing process performance. Thus, the supply flow rate of the dry air or the nitrogen gas that needs to be set to be approximately equivalent to the exhaust flow rate can also be reduced.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic view illustrating an overall configuration of a substrate processing apparatus in accordance with an example embodiment;

FIG. 2A to FIG. 2C are plane views for describing through holes formed in a rectifying plate shown in FIG. 1;

FIG. 3 is a schematic cross sectional view illustrating another configuration example of a switching valve; and

FIG. 4 is a diagram for illustrating a connecting relationship to ports of the switching valve shown in FIG. 3.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current example embodiment. Still, the example embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

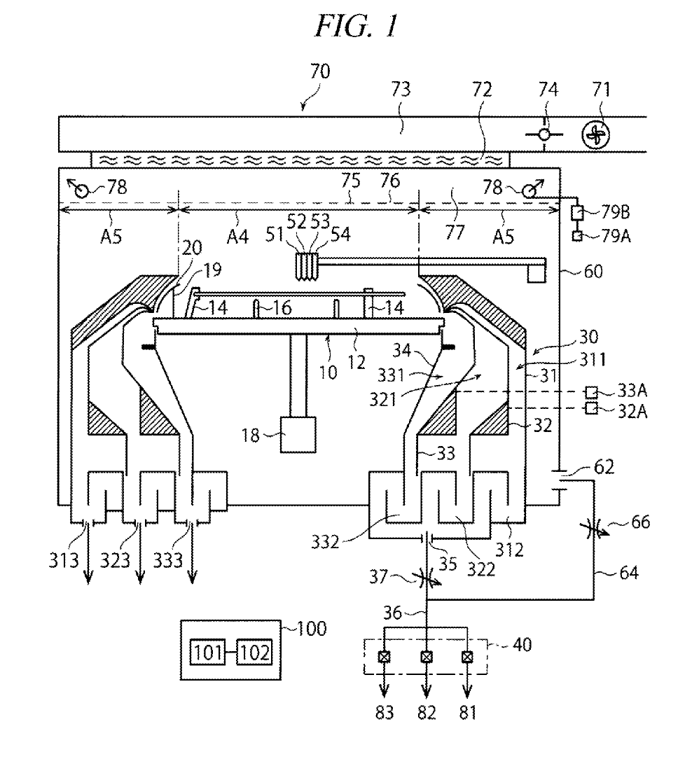

Hereinafter, example embodiments will be described with reference to the accompanying drawings. As depicted in FIG. 1, a substrate processing apparatus includes a substrate holding unit 10 configured to hold thereon a semiconductor wafer (hereinafter, simply referred to as “wafer”) W horizontally. The substrate holding unit 10 includes a circular plate-shaped base 12; and a multiple number of, e.g., three chuck claws 14 fastened to the base 12. The substrate holding unit 10 serves as a mechanical spin chuck configured to hold the wafer W at a multiple number of positions on peripheral portions thereof by the chuck claws 14. The base 12 includes a non-illustrated plate having lift pins 16 configured to lift the wafer W while supporting a rear surface thereof when the wafer W is transferred between an external transfer arm and the base 12. The substrate holding unit 10 can be rotated by a rotation driving unit 18 having an electric motor, so that the wafer W held on the substrate holding unit 10 can also be rotated about a vertical axis line. A ring-shaped rotary cup 20 is fastened to the base 12 via a supporting column 19. The rotary cup 20 is configured to receive, on an inner surface thereof, a processing liquid that is dispersed from the wafer W being rotated, and is configured to guide the received processing liquid into a cup unit 30 that is provided to collect the processing liquid. The cup unit 30 will be described later. The above-described configuration is described in detail in Japanese Patent Laid-open Publication No. 2011-071477 filed by the present applicant.

The cup unit 30 includes a stationary first annular cup 31 located at an outermost position thereof; an annular second cup 32 provided at an inner position than the first cup 31 and configured to be movable up and down; an annular third cup 33 provided at an inner position than the second cup 32 and configured to be movable up and down; and a stationary inner wall 34 positioned at an inner position than the third cup 33. The second cup 32 and the third cup 33 are moved up and down by elevating devices 32A and 33A schematically illustrated in FIG. 1, respectively. A first flow path 311 is formed between the first cup 31 and the second cup 32; a second flow path 321 is formed between the second cup 32 and the third cup 33; and a third flow path 331 is formed between the third cup 33 and the inner wall 34. A cup exhaust opening 35 communicating with the first, second and third flow paths 311, 321 and 331 is formed in a bottom of the cup unit 30.

A cup exhaust path 36 is connected to the cup exhaust opening 35. A flow rate control valve 37, e.g., a butterfly valve is provided on the way of the cup exhaust path 36. A switching valve 40 is provided at a downstream side of the cup exhaust path 36 and is configured to selectively connect the cup exhaust path 36 to an acidic atmosphere exhaust line 81, an alkaline atmosphere exhaust line 82 or an organic atmosphere exhaust line 83.

Each of the first, second and third flow paths 311, 321 and 331 has a bent portion. As a direction of each flow path is sharply changed at the bent portion, a liquid component is separated from a gas-liquid mixture fluid flowing in each flow path. The separated liquid component falls down into a liquid sump 312 corresponding to the first flow path 311, a liquid sump 322 corresponding to the second flow path 321 and a liquid sump 332 corresponding to the third flow path 331. The liquid sumps 312, 322 and 332 are connected to an acidic liquid waste system, an alkaline liquid waste system and an organic liquid waste system (all of them are not illustrated) of a factory via liquid drain openings 313, 323 and 333 corresponding thereto, respectively.

The substrate processing apparatus is equipped with a multiple number of processing liquid nozzles configured to discharge (supply) processing liquids toward the wafer W held on and rotated by the substrate holding unit 10. In this example embodiment, an acidic chemical liquid nozzle 51 configured to discharge an acidic cleaning liquid (e.g., dilute hydrofluoric acid (DHF)), an alkaline chemical liquid nozzle 52 configured to discharge an alkaline cleaning liquid (e.g., SC-1) and a rinse liquid nozzle 53 configured to discharge a rinse liquid (e.g., DIW (pure water)) are provided. Further, a drying accelerating liquid nozzle 54 configured to supply a drying accelerating liquid (e.g., isopropyl alcohol (IPA)) is provided. The respective processing liquids are supplied to the corresponding liquid nozzles from non-illustrated processing liquid supply devices connected to processing liquid supply sources, respectively. Each of processing liquid supply devices has a processing liquid supply path having an opening/closing valve and a flow rate controller such as a flow rate control valve.

The substrate holding unit 10 and the cup unit 30 are accommodated in a housing 60. A fan filter unit (FFU) 70 is provided at a ceiling of the housing 60. The FFU 70 includes a fan 71 configured to introduce air in a clean room; and a filter (specifically, a ULPA filter) 72 configured to filter the introduced air. Within a duct 73 of the FFU 70, a damper 74 capable of blocking ventilation in the duct 73 is provided between a downstream side of the fan 71 and an upstream side of the filter 72.

A rectifying plate 75 having a multiple number of through holes 76 is provided under the ceiling of the housing 60. The rectifying plate 75 is configured to rectify clean air (CA) discharged downwards from the FFU 70 such that the clean air (CA) mainly flows on the wafer W. In a space 77 between the ceiling of the housing 60 and the rectifying plate 75, there is provided a gas nozzle 78 configured to discharge a nitrogen gas or dry air into the space 77. A nitrogen gas or dry air is supplied into the gas nozzle 78 from a gas supply device 79B. The gas supply device 79B is connected to a gas supply source 79A (a nitrogen gas bottle or a dry air generating device) and has a gas supply path on which an opening/closing valve and a flow rate controller such as a flow rate control valve are provided. The gas supplied from the gas nozzle 78 is discharged downwards through the through holes 76 of the rectifying plate 75 after diffused in the space 77. The dry air may be used when a low-humidity atmosphere is required, and the nitrogen gas may be used when a low-humidity and low-oxygen concentration atmosphere is required.

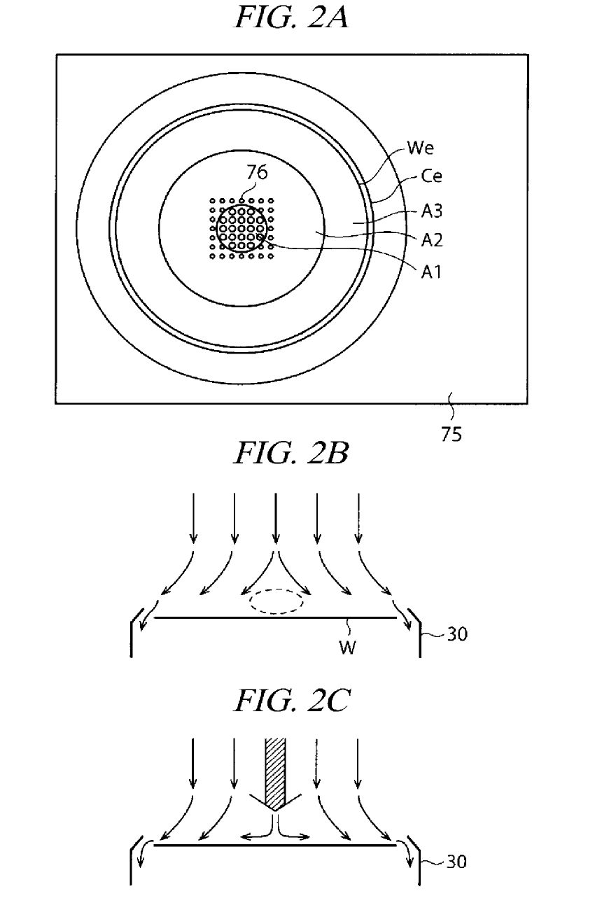

FIG. 2A is a schematic plane view of the rectifying plate 75, when viewed from above, and it illustrates arrangement of the through holes 76. In FIG. 2A, a circle marked by a notation We indicates an edge of the wafer W held on the substrate holding unit 10, and a circle marked by a notation Ce indicates an outline of a top opening of the first cup 31 of the cup unit 30. Only a part of the through holes 76 is illustrated in FIG. 2A, and the through holes 76 are provided such that central portions thereof are arranged in a square lattice shape, i.e., at the same pitch in X and Y directions (for example, at a pitch of about 12 mm in both X and Y directions). A region corresponding to a central portion of the wafer W held on the substrate holding unit 10 is indicated by a notation A1, and a region at an outside of the region A1 is indicated by a notation A2. When the wafer W has a diameter of about 12 inches, for example, the region A1 may be a circular area having a diameter of, e.g., about 62 mm and the region A2 may be a ring-shaped area having a inner diameter of, e.g., about 62 mm and an outer diameter of, e.g., about 200 mm. Through holes 76 provided in the region A1 have the largest diameter, e.g., about 10 mm, and through holes 76 provided in the region A2 have a smaller diameter of, e.g., about 6 mm. Through holes 76 provided in a region A3 at an outside of the region A2 have the smallest diameter of, e.g., about 3 mm. That is, an opening ratio per a unit area is highest in the region A1 and decreases in the order of A2 and A3.

If the opening ratio of the through holes 76 per a unit area is uniform, a downflow may be diffused outwards in a radial direction by being attracted by an air current introduced into the cup unit 30 and may not reach the central portion of the wafer W, as illustrated in FIG. 2B. For this reason, an atmosphere or mist of a processing liquid generated in a liquid process may stay in a region (surrounded by a dashed line) directly above the central portion of the wafer W, so that particles may be generated. However, by increasing the opening ratio of the rectifying plate 75 in the region facing the central portion of the wafer W, a strong downflow toward the central portion of the wafer W may be generated, as shown in FIG. 2C, so that this downflow may reach the central portion of the wafer W without being affected greatly by the air current introduced into the cup unit 30. Thus, it is possible to suppress particle generation that might be caused for the aforementioned reason.

A housing exhaust opening 62 configured to exhaust an atmosphere within the housing 60 is formed at a lower portion of the housing 60 (specifically, at a position lower than a top opening of the cup unit 30) to be located at an outside of the cup unit 30. A housing exhaust path 64 is connected to the housing exhaust opening 62. The housing exhaust path 64 is equipped with a flow rate control valve 66, e.g., a butterfly valve and is connected to a portion of the cup exhaust path 36 between the flow rate control valve 37 and the switching valve 40.

As schematically illustrated in FIG. 1, the substrate processing apparatus has a controller (control unit) 100 configured to control an overall operation thereof. That is, the controller 100 controls operations of all functional components of the substrate processing apparatus (for example, the rotation driving unit 18, the elevating devices 32A and 33A of the second and third cups 32 and 33, the non-illustrated processing liquid supply device, the flow rate control valves 37 and 66, the switching valve 40, the FFU 70, the gas supply device 79B, etc.). By way of non-limiting example, the controller 100 may be implemented by a general-purpose computer as hardware and programs (including an apparatus control program, processing recipes, etc.) as software for operating the computer. The software may be stored in a storage medium such as a hard disk drive fixed in the computer, or may be stored in a storage medium detachably set in the computer, such as a CD-ROM, a DVD, a flash memory, etc. Such a storage medium is indicated by a reference numeral 101 in FIG. 1. A processor 102 reads out a necessary processing recipe from the storage medium 101 in responses to an instruction from a non-illustrated user interface and executes the processing recipe, so that each functional component of the substrate processing apparatus is operated under the control of the controller 100, and a preset process is performed.

Now, an operation of the substrate processing apparatus performed under the control of the controller 100 will be discussed.

(Acidic Chemical Liquid Cleaning Process)

A wafer W is held by the substrate holding unit 10 and is rotated by the rotation driving unit 18. As a processing liquid, an acidic chemical liquid, e.g., DHF is supplied onto the rotating wafer W from the acidic chemical liquid nozzle 51, and an acidic chemical liquid cleaning process is performed on the wafer W. The acidic chemical liquid is dispersed from the wafer W by a centrifugal force and received by the rotary cup 20. At this time, the second cup 32 and the third cup 33 are located at lowered positions, and the acidic chemical liquid flows through the first flow path 311 between the first cup 31 and the second cup 32.

At this time, the damper 74 of the FFU 70 is in an open state and the fan 71 is being rotated. Accordingly, clean air flows downwards toward the wafer W from the through holes 76 of the rectifying plate 75. That is, a downflow of the clean air is formed under the rectifying plate 75 within the housing 60.

Further, at this time, the switching valve 40 allows the cup exhaust path 36 and the acidic atmosphere exhaust line 81 to communicate with each other. Accordingly, a gas (in this example, the clean air that forms the downflow) that exists in the space above the wafer W is introduced into the cup unit 30 through the top opening of the first cup 31 and flows through the first flow path 311 between the first cup 31 and the second cup 32. Then, the gas is exhausted from the cup exhaust opening 35 and flows through the acidic atmosphere exhaust line 81 via the cup exhaust path 36 and the switching valve 40. Thus, even if an acidic chemical liquid atmosphere (processing liquid atmosphere) including acidic chemical liquid mist (fine liquid droplets) exists in the space above the wafer W, the acidic chemical liquid atmosphere can be exhausted through the cup exhaust opening 35 and may not remain in the space (the region A4 in FIG. 1) above the wafer W. As a result, it is possible to suppress a subsequent process from being affected by the staying processing liquid atmosphere, and also possible to suppress the inner wall of the housing from being contaminated by the staying processing liquid atmosphere.

Further, a part of the acidic chemical liquid is turned into the form of mist as a result of colliding with the wafer, the rotary cup 20, the first cup 31, etc. This mist is introduced into the cup unit 30, so that it flows toward the cup exhaust opening 35 by being carried on the gas flowing through the first flow path 311. Most of this mist may be captured by a wall of the bent portion of the first flow path 311 and fall down into the liquid sump 312. Further, the acidic chemical liquid that flows down along the surfaces of the first cup 31 and the second cup 32 facing the first flow path 311 may also fall down into the liquid sump 312. The acidic chemical liquid collected in the liquid sump 312 is discharged out of the cup unit 30 through the liquid drain opening 313.

Further, a gas that exists in a space around the cup unit 30 within the housing 60 (specifically, a gas existing in a space at an outside of a lateral periphery of the first cup 31 in a radial direction (region A5 in FIG. 1) and a part of a gas existing in a region close to this space) may be exhausted from the housing exhaust opening 62 and flown into the acidic atmosphere exhaust line 81 via the housing exhaust path 64 and the switching valve 40. Accordingly, even if an acidic chemical liquid atmosphere including acidic chemical liquid vapor or acidic chemical liquid mist exists in the space around the cup unit 30, which may not be exhausted from the cup exhaust opening 35, such acidic chemical liquid atmosphere can be suppressed from staying in the space around the cup unit 30. Therefore, it is possible to suppress a subsequent process from being affected by a staying processing liquid atmosphere, and also possible to suppress the inner wall of the housing from being contaminated by the staying processing liquid atmosphere.

(First Rinse Process)

Subsequently, while rotating the wafer W, the discharge of the acidic chemical liquid from the acidic chemical liquid nozzle 51 is stopped, and a rinse liquid, e.g., DIW is supplied onto the wafer W from the rinse liquid nozzle 53 as a processing liquid. As a result, the acidic chemical liquid and its residue remaining on the wafer W are cleaned. This rinse process is different from the acidic chemical liquid cleaning process only in this operation, and the other operations (flows of a gas and a processing liquid) are the same as those in the acidic chemical liquid cleaning process.

(Alkaline Chemical Liquid Cleaning Process)

Thereafter, while rotating the wafer W, the discharge of the rinse liquid from the rinse liquid nozzle 53 is stopped. Then, the third cup 33 remains at the lowered position, and the second cup 32 is moved to a raised position. Further, by switching the switching valve 40, the cup exhaust path 36 and the alkaline atmosphere exhaust line 82 are allowed to communicate with each other. Subsequently, as a processing liquid, an alkaline cleaning liquid, e.g., SC-1 is supplied from the alkaline chemical liquid nozzle 52 onto the wafer W, so that an alkaline chemical liquid cleaning process is performed on the wafer W. This alkaline chemical liquid cleaning process is different from the acidic chemical liquid cleaning process in exhaust paths of a gas and the alkaline chemical liquid, and the other operations are the same as those of the acidic chemical liquid cleaning process.

That is, after a gas in the space above the wafer W is introduced into the cup unit 30 through the top opening of the first cup 31, this gas flows through a second flow path 321 between the second cup 32 and the third cup 33. Then, the gas is exhausted from the cup exhaust opening 35 and flows into the alkaline atmosphere exhaust line 82 via the cup exhaust path 36 and the switching valve 40. The chemical liquid dispersed from the wafer W flows through the second flow path 321 and falls down into the liquid sump 322. Then, the chemical liquid is discharged out of the cup unit 30 through the liquid drain opening 323. Meanwhile, a gas that exists in the space around the cup unit 30 within the housing 60 is exhausted from the housing exhaust opening 62 and flows into the alkaline atmosphere exhaust line 82 via the housing exhaust path 64 and the switching valve 40. Thus, as in the acidic chemical liquid cleaning process, it is possible to suppress the processing liquid atmosphere from staying within the housing 60.

(Second Rinse Process)

Thereafter, while rotating the wafer W, the discharge of the alkaline chemical liquid from the alkaline chemical liquid nozzle 52 is stopped, and the rinse liquid is supplied onto the wafer W from the rinse liquid nozzle 53 instead, so that the alkaline chemical liquid and its residue remaining on the wafer W are cleaned. This second rinse process is the same as the first rinse process excepting that the exhaust paths of a gas and the processing liquid (rinse liquid) are different from those in the first rinse process.

(Drying Process)

Then, while rotating the wafer W, the discharge of the rinse liquid from the rinse liquid nozzle 53 is stopped. The second cup 32 remains at the raised position, and the third cup 33 is moved to a raised position (this state is shown in FIG. 1). Further, by switching the switching valve 40, the cup exhaust path 36 and the organic atmosphere exhaust line 83 are allowed to communicate with each other. Almost concurrently, the fan 71 of the FFU 70 is stopped, and the damper 74 is then closed. Immediately thereafter, a nitrogen gas (or dry air) is discharged from the gas nozzle 78. Then, as a processing liquid, the drying accelerating liquid, e.g., IPA is supplied from the drying accelerating liquid nozzle 54 onto the wafer W for a preset period of time. Then, the supply of the drying accelerating liquid from the drying accelerating liquid nozzle 54 is stopped, and the wafer W is rotated for a certain period of time. Through this operation, DIW remaining on the wafer W is absorbed into the IPA. Then, by dispersing and evaporating the IPA from the wafer W, the wafer W is dried.

While the drying process is being performed, a nitrogen gas, having a low humidity and a low oxygen concentration, flows down toward the wafer W from the through holes 76 of the rectifying plate 75. The downflow of the nitrogen gas is introduced into the cup unit 30 through the top opening of the first cup 31. Then, after flowing through the third flow path 331 between the third cup 33 and the inner wall 34, the nitrogen gas is exhausted from the cup exhaust opening 35 and flows into the organic atmosphere exhaust line 83 via the cup exhaust path 36 and the switching valve 40. Accordingly, it is possible to allow the space above the wafer W to be in a low-humidity atmosphere. Meanwhile, by controlling the flow rate control valve 66, an exhaust flow rate from the housing is set to be smaller than that in case of performing a liquid process (e.g., about 1/10 of an exhaust flow rate in a liquid process).

Further, a part of the drying accelerating liquid is turned into the form of mist as a result of colliding with the wafer, the rotary cup 20, the third cup 33, etc. This mist is introduced into the cup unit 30, so that it flows toward the cup exhaust opening 35 by being carried on the gas flowing through the third flow path 331. Most of the mist may by captured by a wall of the bent portion formed on the way of the third flow path 331 and fall down into the liquid sump 332. Further, the drying accelerating liquid that flows down along the surfaces of the third cup 33 and the inner wall 34 facing the third flow path 331 may also fall down into the liquid sump 332. The drying accelerating liquid collected in the liquid sump 332 is discharged out of the cup unit 30 through the liquid drain opening 333.

Upon the completion of the drying process, the discharge of the nitrogen gas from the gas nozzle 78 is stopped, and the damper 74 is opened and the fan 71 of the FFU 70 is operated. Almost concurrently, the opening degree of the flow rate control valve 66 is returned back into the prior state and the exhaust flow rate from the housing is set to be equal to that in case of performing the liquid process. Further, by switching the switching valve 40, the cup exhaust path 36 and the acidic atmosphere exhaust line 81 are allowed to communicate with each other. In this state, the processed wafer W is unloaded from the housing 60 by a non-illustrated transfer arm. Then, a next wafer W to be processed is loaded into the housing 60 by the non-illustrated transfer arm and held on the substrate holding unit 10. As stated, when loading or unloading the wafer W, a downflow of the clean air supplied from the FFU 70 is formed within the housing 60, and the same cup exhaust and housing exhaust as those in the liquid process are performed.

As discussed above, if an atmosphere of a chemical liquid (an acidic chemical liquid or an alkaline chemical liquid) stays in the internal space of the housing, the staying chemical liquid atmosphere may affect a subsequent process and contaminate the inner wall of the housing. To solve the problems, when performing a chemical liquid process (an acidic chemical liquid cleaning process and an alkaline chemical liquid cleaning process), clean air is supplied by the FFU 70 at a relatively high flow rate (e.g., about 1200 liters per minute), and exhaust is performed at a flow rate approximately corresponding to the supply flow rate of the clean air. By way of example, but not limitation, a flow rate of the exhaust through the cup exhaust opening 35 (hereinafter, simply referred to as “cup exhaust”) is set to be about 1000 liters per minute, and a flow rate of the exhaust through the housing exhaust opening 62 (hereinafter, simply referred to as “housing exhaust”) is set to be about 200 liters per minute. In this way, by introducing the clean air of such a relatively high flow rate into the cup unit 30, it is possible to suppress the chemical liquid, which is turned into the form of mist by colliding with the wall surfaces of the cup unit 30 after dispersed from the wafer W, from flowing back toward the wafer W. Further, even if the chemical liquid, which is turned into mist or vaporized, enters the space above the wafer W from the space around the cup unit 30 within the housing 60, such chemical liquid may be immediately introduced into the cup unit 30 by being carried on the flow of the clean air supplied into the cup unit 30. Further, the chemical liquid, which is turned into the mist or vaporized, staying in the space around the cup unit 30 within the housing 60 may be discharged out of the housing 60 by being carried on the flow of the housing exhaust. Here, if the flow rate of the housing exhaust is set to be excessively great, the downflow of the clean air toward the wafer W may be attracted by the air current flowing toward the housing exhaust opening 62, so that the most important air flow directly above the wafer W may be disturbed. Thus, the flow rate of the housing exhaust is set to be smaller than the flow rate of the cup exhaust.

When the chemical liquid processes are performed, it may be desirable that a pressure within the housing 60 is set to be equal to or slightly lower than a pressure within the outside of the housing 60 in order to suppress the chemical liquid atmosphere within the housing 60 from being leaked into the outside of the housing 60. Meanwhile, when the drying process is performed, it is desirable that the pressure within the housing 60 is set to be equal to or slightly higher than the pressure within the outside of the housing 60 in order to suppress the air within the outside of the housing 60 having a high humidity (or having more particles as compared to the air within the housing 60) from being introduced into the internal space of the housing 60. That is, in any cases, it may be desirable that the pressure within the housing 60 is set to be approximately equal to the pressure within the outside (clean room) of the housing 60. For this reason, the flow rate of the gas discharged through the through holes 76 of the rectifying plate 75 needs to be substantially equal to the total flow rate of the cup exhaust and the housing exhaust.

When the drying process is performed, the chemical liquid atmosphere does not exist in the space above the wafer W and the space around the cup unit 30, and these spaces are sufficiently cleaned. Further, the space above the wafer W is set in a low-humidity atmosphere. For this reason, the flow rate of the housing exhaust can be set to be smaller than that in case of performing the liquid processes as stated above. Further, the flow rate of the cup exhaust is also set to be smaller than that in case of performing the liquid processes, e.g., about 500 liters per minute. Accordingly, the flow rate of the nitrogen gas (or dry air) discharged from the gas nozzle 78 is set to be about 500 liters per minute, which is equal to the flow rate of the cup exhaust. The object of the supply of the nitrogen gas (or dry air) is mainly to facilitate the drying of the wafer W by reducing the humidity around the wafer W, and is not to remove an atmosphere that may cause contamination. Thus, it is not required to supply the nitrogen gas (or dry air) at a high flow rate.

In accordance with the above-described example embodiment, when the drying process is performed, the total flow rate of the housing exhaust and the cup exhaust is smaller, as compared to that in case of performing a liquid process such as the chemical liquid processes or the rinse processes. Accordingly, it may be possible to reduce a low-humidity gas amount, corresponding to the total exhaust flow rate, such as the nitrogen gas of a high price (or the dry air that requires great power and high cost) that needs to be supplied into the housing 60. Since the necessary air flow is obtained even in such a case, the process performance (process result) may not be decreased.

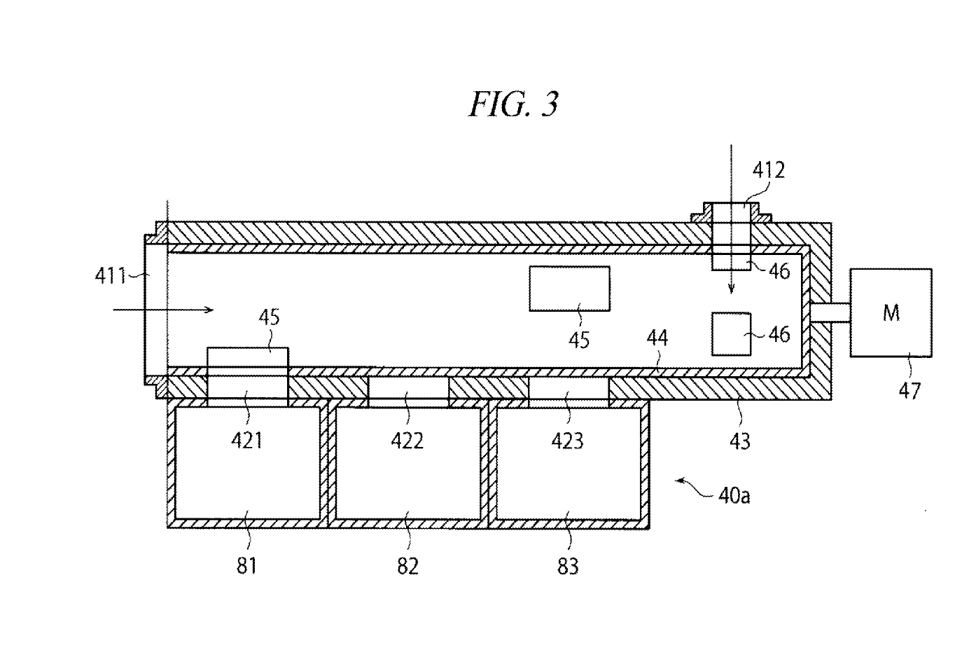

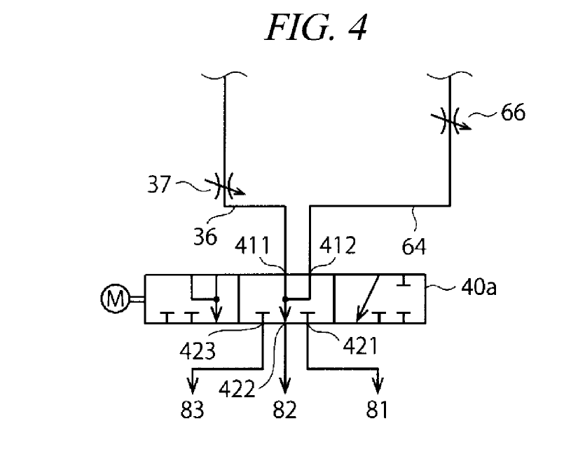

Now, another example embodiment will be explained with reference to FIG. 3 and FIG. 4. This example embodiment is different from the above-described example embodiment in that a switching valve 40a of a rotary type is used instead of the switching valve 40. The switching valve 40a has a first intake port 411 connected to the cup exhaust path 36 and a second intake port 412 connected to the housing exhaust path 64. Unlike the example embodiment depicted in FIG. 1, the cup exhaust path 36 and the housing exhaust path 64 do not meet with each other at the upstream side of the switching valve 40a. Further, the switching valve 40a also has a first exhaust port 421 connected to the acidic atmosphere exhaust line (acidic atmosphere exhaust system) 81; a second exhaust port 422 connected to the alkaline atmosphere exhaust line (alkaline atmosphere exhaust system) 82; and a third exhaust port 423 connected to the organic atmosphere exhaust line (organic atmosphere exhaust system) 83 of the factory.

FIG. 3 schematically illustrates a configuration of the switching valve 40a. A valve box 43 of the switching valve 40a is mounted on the acidic atmosphere exhaust line 81, the alkaline atmosphere exhaust line 82 and the organic atmosphere exhaust line 83 each of which is formed as a duct having a rectangular cross section. A gas flows in each of the exhaust lines 81 to 83 in a direction orthogonal to the paper plane of the drawing. One end of the valve box 43 is opened to be used as the first intake port 411, and the cup exhaust path 36 (not shown in FIG. 3) is connected to the first intake port 411. The valve box 43 has a cylindrical internal space, and a hollow cylindrical valve body 44 is accommodated in the internal space of the valve box 43. One end of the valve body 44 is opened and the other end is closed. The valve body 44 is configured to be rotated by an appropriate rotation driving device 47, e.g., a step motor and can be stopped at a certain rotation phase.

One opening is formed in a top surface of each of the ducts serving as the exhaust lines 81, 82 and 83. Openings as the first, second and third exhaust ports 421, 422 and 423 are formed in a bottom of the valve box 43 and connected to the openings of the ducts of the exhaust lines 81, 82 and 83, respectively. The hollow cylindrical valve body 44 has three valve body openings 45 (one of them is not illustrated in FIG. 3). The three valve body openings 45 are formed at the same positions as the first, second and third exhaust ports 421, 422 and 423 in an axis line direction (in an axis line direction of the valve body 44), respectively. Further, the three valve body openings 45 are deviated from each other at an angular interval of about 120° along a circumference of the valve body 44.

An opening as the second intake port 412 is formed at the other end side of the valve box 43. Further, the hollow cylindrical valve body 44 also has two valve body openings 46. The two valve body openings 46 are formed at the same position as the second intake port 412 in an axis line direction and are deviated from each other at an angular interval of about 120°.

The three valve body openings 45 and the two valve body openings 46 are in positional relationship as described below. When the valve body 44 is in a first rotation position (e.g., at a position of 0° as a reference position), the opening serving as the first exhaust port 421 and one valve body opening 45 are connected with each other and, also, the opening serving as the second intake port 412 and one valve body opening 46 are connected with each other. As a result, the cup exhaust opening 35 and the housing exhaust opening 62 are connected to the acidic atmosphere exhaust line 81, and the atmosphere within the cup unit 30 and the housing 60 is sucked up by a negative pressure of the acidic atmosphere exhaust line 81. When the valve body 44 is in a second rotation position (at a position further rotated from the reference position by about 120°), the opening serving as the second exhaust port 422 and another valve body opening 45 are connected with each other and, also, the opening serving as the second intake port 412 and the other valve body opening 46 are connected with each other. As a result, the cup exhaust opening 35 and the housing exhaust opening 62 are connected to the alkaline atmosphere exhaust line 82, and the atmosphere within the cup unit 30 and the housing 60 is sucked up by a negative pressure of the alkaline atmosphere exhaust line 82. When the valve body 44 is in a third rotation position (at a position further rotated from the reference position by about 240°), the opening serving as the third exhaust port 423 and the other valve body opening 45 are connected with each other and, also, the second intake port 412 is closed by the valve body 44. As a result, the cup exhaust opening 35 is connected to the organic atmosphere exhaust line 83, and the atmosphere within the cup unit 30 is suck up by a negative pressure of the organic atmosphere exhaust line 83. That is, exhaust from the housing exhaust opening 62 is not performed. The connecting relationship to the ports may be understood by referring to FIG. 4. Further, the switching valve 40a may be configured to have a fourth rotation position of the valve body 44 where all the ports are closed. Alternatively, opening/closing valves may be provided on the cup exhaust path 36 and the housing exhaust path 64.

By allowing the valve body 44 to be in the first rotation position when the acidic chemical liquid cleaning process and the first rinse process are performed; to be in the second rotation position when the alkaline chemical liquid cleaning process and the second rinse process are performed; and to be in the third rotation position when the drying process is performed, the same processes as in the example embodiment of FIG. 1 can be performed. In the structure of the switching valve 40a, the switching control between the cup exhaust and the housing exhaust can be performed by a single driving unit.

In the example embodiment shown in FIG. 3 and FIG. 4, during the drying process, a flow rate of the housing exhaust is reduced to 0 (zero). By reducing the flow rate of the housing exhaust to 0 (zero), the control thereof may be easily performed. Meanwhile, in the example embodiment of FIG. 1, by reducing the opening degree of the flow rate control valve 66, the flow rate of the housing exhaust is reduced to, e.g., about 1/10 of that in case of performing a liquid process. In all cases, it may be desirable to reduce the total flow rate of the cup exhaust and the housing exhaust by mainly decreasing the housing exhaust, which is less necessary in the drying process. Further, it may be desirable to reduce the flow rate of the cup exhaust in the drying process to a certain level where appropriate air flow can be generated in the cup unit 30.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

We claim:

1. A substrate processing apparatus, comprising:
a substrate holding unit configured to hold thereon a substrate horizontally;
a rotation driving unit configured to rotate the substrate holding unit about a vertical axis line;
a processing liquid nozzle configured to supply a processing liquid onto the substrate;
a cup unit, having a top opening and surrounding the substrate held on the substrate holding unit, configured to collect the processing liquid;
a housing having an internal space in which the substrate holding unit, the processing liquid nozzle and the cup unit are accommodated;
a clean gas supply device configured to selectively supply a first clean gas and a second clean gas having a humidity lower than that of the first clean gas into a space above the cup unit within the internal space of the housing;
a cup exhaust path through which an atmosphere within the cup unit is exhausted;
a housing exhaust path, having an exhaust opening formed at a position in the internal space of the housing and at an outside of the cup unit, through which an atmosphere in the internal space of the housing is exhausted without passing through an inside of the cup unit;
an exhaust flow rate controller provided on the housing exhaust path; and
a controller configured to control the exhaust flow rate controller such that a flow rate of the second clean gas supplied when a drying process is performed on the substrate is set to be smaller than a flow rate of the first clean gas supplied when a liquid process is performed by supplying the processing liquid onto the substrate from the processing liquid nozzle, and such that a flow rate of a gas exhausted through the housing exhaust path when the drying process is performed is set to be smaller than a flow rate of a gas exhausted through the housing exhaust path when the liquid process is performed.

2. The substrate processing apparatus of claim 1,
wherein the controller is configured to set a flow rate of a gas exhausted through the cup exhaust path when the drying process is performed to be smaller than a flow rate of a gas exhausted through the cup exhaust path when the liquid process is performed.

3. The substrate processing apparatus of claim 1,
wherein the first clean gas is air within a clean room supplied and filtered by a fan filter unit, and the second clean gas is clean dry air or a nitrogen gas.

4. The substrate processing apparatus of claim 1, further comprising:
a drying accelerating fluid nozzle configured to supply a drying accelerating fluid onto the substrate when the drying process is performed.

5. The substrate processing apparatus of claim 4,
wherein the drying accelerating fluid includes isopropyl alcohol.

6. The substrate processing apparatus of claim 1,
wherein the clean gas supply device has a rectifying plate that faces the internal space of the housing,
the rectifying plate is provided with a multiple number of openings through which the clean gas is discharged downwards toward the internal space of the housing, and
when the substrate is held on the substrate holding unit, an opening ratio in a region of the rectifying plate directly above a central portion of the substrate is larger than an opening ratio in a region of the rectifying plate directly above a peripheral portion of the substrate.

7. A substrate processing method performed by using a substrate processing apparatus including:
a substrate holding unit configured to hold thereon a substrate horizontally;
a rotation driving unit configured to rotate the substrate holding unit about a vertical axis line;
a processing liquid nozzle configured to supply a processing liquid onto the substrate;
a cup unit having a top opening and surrounding the substrate held on the substrate holding unit, configured to collect the processing liquid;
a housing having an internal space in which the substrate holding unit, the processing liquid nozzle and the cup unit are accommodated;
a clean gas supply device configured to selectively supply a first clean gas and a second clean gas having a humidity lower than that of the first clean gas into a space above the cup unit within the internal space of the housing;
a cup exhaust path through which an atmosphere within the cup unit is exhausted;
a housing exhaust path, having an exhaust opening formed at a position in the internal space of the housing and at an outside of the cup unit, through which an atmosphere in the internal space of the housing is exhausted without passing through an inside of the cup unit; and
an exhaust flow rate controller provided on the housing exhaust path,
the substrate processing method comprising:
setting a flow rate of the second clean gas supplied when a drying process is performed on the substrate to be smaller than a flow rate of the first clean gas supplied when a liquid process is performed by supplying the processing liquid onto the substrate from the processing liquid nozzle; and
setting a flow rate of a gas exhausted through the housing exhaust path when the drying process is performed to be smaller than a flow rate of a gas exhausted through the housing exhaust path when the liquid process is performed.

8. The substrate processing method of claim 7,
wherein a flow rate of a gas exhausted through the cup exhaust path when the drying process is performed is set to be smaller than a flow rate of a gas exhausted through the cup exhaust path when the liquid process is performed.

9. The substrate processing method of claim 7,
wherein the first clean gas is air within a clean room supplied and filtered by a fan filter unit, and the second clean gas is clean dry air or a nitrogen gas.

10. The substrate processing method of claim 7,
wherein the substrate processing apparatus further comprises a drying accelerating fluid nozzle, and
when the drying process is performed, a drying accelerating fluid is supplied onto the substrate held on the substrate holding unit from the drying accelerating fluid nozzle.

11. The substrate processing method of claim 9,
wherein the drying accelerating fluid includes isopropyl alcohol.

12. A computer-readable storage medium having stored thereon computer-executable instructions that, in response to execution, cause a substrate processing apparatus to perform a substrate processing method as claimed in claim 7,
wherein the computer-executable instructions stored on the storage medium are executed by the controller, which is formed of a computer, of the substrate processing apparatus, and the controller controls the substrate processing apparatus.
